(19) United States
(12) Patent Application Publication
(10) Pub. No.: US 2024/0150654 A1
(43) Pub. Date: May 9, 2024

(54) COMPOSITION FOR THE SELECTIVE ETCHING OF SILICON

(71) Applicant: ENF TECHNOLOGY CO., LTD., Gyeonggi-do (KR)

(72) Inventors: Gi Young KIM, Gyeonggi-do (KR); Hak Soo KIM, Gyeonggi-do (KR); Jeong Sik OH, Gyeonggi-do (KR); Myung Ho LEE, Gyeonggi-do (KR); Myung Geun SONG, Gyeonggi-do (KR)

(21) Appl. No.: 18/077,509

(22) Filed: Dec. 8, 2022

(30) Foreign Application Priority Data
Oct. 20, 2022 (KR) 10-2022-0135327

(51) Int. Cl. C09K 13/08

(52) U.S. Cl. CPC C09K 13/08; H01L 21/30604

(57) ABSTRACT

The present invention relates to a composition for selectively etching silicon on a surface on which a silicon oxide film (SiO₂) and silicon (Si) are exposed. According to the present invention, it is possible to improve etch selectivity of silicon on the semiconductor surface.

### CROSS REFERENCE TO RELATED APPLICATIONS

This application claims the benefit of priority to Korean Patent Application No. 10-2022-0135327 filed on Oct. 20, 2022, incorporated herein by reference.

### TECHNICAL FIELD

The present invention relates to a composition for selectively etching silicon on a surface on which a silicon oxide film (SiO₂) and silicon (Si) are exposed.

### BACKGROUND ART

A silicon oxide film (SiO₂) and a silicon nitride film (SiN) are used as main insulating films in semiconductors.

However, the conventional acidic etchants have problems in that an exposed lower metal layer is damaged due to low selectivity to a silicon oxide layer and a silicon nitride layer.

Accordingly, the acidic etchants have limitations in application to processes such as wafer thinning, semiconductor packaging, and Through Silicon Via (TSV). In the case of the conventional acidic etchants, the application of the silicon oxide film exposure process/device, which influences most of the exposed film quality in the semiconductor process, is limited due to the non-selective etching of the silicon oxide film.

Therefore, it is necessary to study a composition that has a very low etch rate of the silicon oxide film and can selectively etch only silicon.

### DETAILED DESCRIPTION OF THE INVENTION

### Technical Problem

It is an object of the present invention to provide a composition having the improved etch selectivity of silicon to a silicon oxide film.

### Solution to Problem

In order to solve the above problems, the present invention provides a composition for selective etching of silicon, comprising:
a fluorine compound;
nitric acid;
phosphoric acid;
acetic acid; and
a nitrite compound.

According to one embodiment, the fluorine compound may comprise one or more of hydrofluoric acid, ammonium bifluoride, sodium fluoride, potassium fluoride, aluminum fluoride, fluoroboric acid, ammonium fluoride, sodium bifluoride, potassium bifluoride, and ammonium tetrafluoroborate.

According to one embodiment, the nitrite compound may have a structure of chemical formula 1 or chemical formula 2:

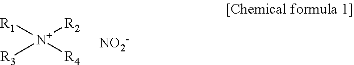

wherein R₁ to R₄ are each independently a hydrogen atom, C₁₋₆ alkyl or C₃₋₈ cycloalkyl;

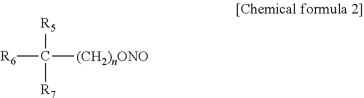

wherein R₅ to R₇ are each independently a hydrogen atom or C₁₋₃ alkyl, and
n is an integer of 0 to 6.

According to one embodiment, the nitrite compound may comprise one or more of tetrabutylammonium nitrite, dicyclohexylamine nitrite, tert-butyl nitrite, isopentyl nitrite, butyl nitrite, ethyl nitrite, isobutyl nitrite, and pentyl nitrite.

According to one embodiment, the etch rate of silicon in the present invention may be 7 μm/min or more, and the etch selectivity of silicon to the silicon oxide film may be 50 or more.

According to other embodiment of the present invention, there is provided a method for preparing a composition for selective etching of silicon, comprising mixing, based on the total weight of the composition,
0.01 to 20% by weight of a fluorine compound;
20 to 90% by weight of nitric acid;
0.1 to 20% by weight of phosphoric acid;
0.01 to 10% by weight of acetic acid; and
0.001 to 15% by weight of a nitrite compound.

According to one embodiment, the nitrite compound may comprise one or more of tetrabutylammonium nitrite, dicyclohexylamine nitrite, tert-butyl nitrite, isopentyl nitrite, butyl nitrite, ethyl nitrite, isobutyl nitrite, and pentyl nitrite.

According to another embodiment of the present invention, there is provided a semiconductor device manufactured using the composition for selective etching of silicon as described above.

The specific details of other embodiments according to the present invention are included in the detailed description below.

### Effect of the Invention

According to the present invention, it is possible to improve etch selectivity of silicon from the semiconductor surface on which both of a silicon oxide film and silicon are exposed.

### BEST MODE FOR CARRYING OUT THE INVENTION

The present invention may have various modification and various embodiments, and specific embodiments will be described in detail. However, it is not intended to limit the present invention to specific embodiments, and should be understood to include all modifications, equivalents, and substitutes included in the spirit and scope of the present invention. In describing the present invention, if it is determined that a detailed description of a related known technology may obscure the gist of the present invention, the detailed description thereof will be omitted.

As used herein, unless otherwise specified, the expression “to” in relation to a number is used as an expression including the corresponding numerical value. Specifically, for example, the expression “1 to 2” is meant to include all numbers between 1 and 2 as well as 1 and

In a semiconductor, silicon is oxidized to a silicon oxide film by oxidizing species generated from an oxidizing agent and an auxiliary oxidizing agent. The oxidized silicon oxide film is etched by contact with an etchant. When etching silicon, the etch selectivity of silicon relative to the silicon oxide film should be high in order to minimize defects in the lower pattern and wiring short circuit.

In the present invention, a selective etching effect of silicon to a silicon oxide film (SiO₂) was improved by providing a specific combination of composition and conditions.

Hereinafter, the composition the selective etching of silicon according to embodiments of the present invention will be described in more detail.

Specifically, the present invention provides a composition for selective etching of silicon, comprising a fluorine compound; nitric acid; phosphoric acid; acetic acid; and a nitrite compound.

The fluorine compound of the present invention, which is a compound that dissociates to generate F⁻ or HF²⁻ having strong affinity with silicon, serves to etch the silicon oxide film. The fluorine compound may comprise one or more of hydrofluoric acid (HF), ammonium bifluoride (ABF; NH₄HF₂), sodium fluoride (Nan, potassium fluoride (KF), aluminum fluoride (AlF₃), fluoroboric acid (HBF₄), ammonium fluoride (NH₄F), sodium bifluoride (NaHF₂), potassium bifluoride (KHF₂) and ammonium tetrafluoroborate (NH₄BF₄). Specifically, it may comprise one or more of hydrofluoric acid, ammonium fluoride, and ammonium bifluoride, for example.

The content of the fluorine compound may be from 0.01 to 20% by weight, for example 0.1 to 10% by weight, or 1 to 10% by weight, or 1 to 20% by weight, or 1 to 5% by weight, based on the total weight of the composition.

The nitric acid of the present invention may serve as an oxidizing agent to oxidize silicon to etch silicon more effectively. According to one embodiment, the composition of the present invention may contain 20 to 90% by weight of nitric acid, for example, 30 to 80% by weight, or 40 to 60% by weight.

The phosphoric acid of the present invention may serve to control the viscosity. The composition of the present invention may contain 0.1 to 20% by weight of phosphoric acid, for example 5 to 15% by weight based on the total weight of the composition.

The acetic acid of the present invention may serve to prevent the decomposition of nitric acid. The composition of the present invention may contain 0.01 to 10% by weight of acetic acid, for example 0.1 to 10% by weight, or 5 to 10% by weight.

The nitrite compound of the present invention may serve as an auxiliary oxidizing agent to oxidize silicon to etch silicon more effectively. The nitrite compound may include a compound of chemical formula 1 or chemical formula 2.

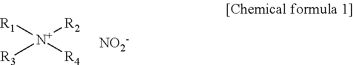

wherein R₁ to R₄ are each independently a hydrogen atom, C₁₋₆ alkyl or C₃₋₈ cycloalkyl;

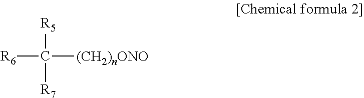

wherein
R₅ to R₇ are each independently a hydrogen atom or C₁₋₃ alkyl, and
n is an integer of 0 to 6.

Specifically, for example, the nitrite compound may comprise one or more of tetrabutylammonium nitrite (TBA), dicyclohexylamine nitrite (DCHA), tert-butyl nitrite (TBN), isopentyl nitrite (IPN), butyl nitrite (BN), ethyl nitrite (EN), isobutyl nitrite, and pentyl nitrite.

According to one embodiment, the composition of the present invention may contain 0.001 to 15% by weight of the nitrite compound, for example 0.1 to 10% by weight, or 0.05 to 5% by weight, or 0.1 to 5% by weight.

The present invention can improve the selective etch rate of silicon e silicon oxide film.

The silicon oxide film is not particularly limited as long as it is a silicon oxide film commonly used in the art, and may be, for example, at least one selected from the group consisting of SOD (Spin On Dielectric) films, HDP (High Density Plasma) films, thermal oxide films, BPSG (Borophosphate Silicate Glass) films, PSG (Phospho Silicate Glass) films, BSG (Boro Silicate Glass) films, PSZ (Polysilazane) films, FSG (Fluorinated Silicate Glass) films, LP-TEOS (Low Pressure Tetra Ethyl Ortho Silicate) films, PETEOS (Plasma Enhanced Tetra Ethyl Ortho Silicate) films, HTO (High Temperature Oxide) films, MTO (Medium Temperature Oxide) films, USG (Undoped Silicate Glass) films, SOG (Spin On Glass) films, APL (Advanced Planarization Layer) films, ALD (Atomic Layer Deposition) films, PE-oxide (Plasma Enhanced oxide) films and O3-TEOS (O3-Tetra Ethyl Ortho silicate).

According to one embodiment, when treating the substrate, the etch rate of silicon may be 7 μm/min or more, or 8 μm/min or more. In addition, the etching selectivity of silicon to the silicon oxide film may be 50 or more, for example 55 or more, 60 or more, or 65 or more.

According to one embodiment, the amount of water such that the total weight of the composition is 100% by weight may be contained in the composition. The water to be used is not particularly limited, but deionized water may be used. Preferably, deionized water having a specific resistance value of 18 MSS/cm or more which indicates the degree of removal of ions in water, may be used.

According to one embodiment, the composition of the present invention may further comprise any additives used in a conventional etchant composition in order to improve etching performance. For example, it may further comprise one or more selected from the group consisting of a stabilizer, a surfactant, an antioxidant, a corrosion inhibitor, and a mixture thereof.

The stabilizer may be an etching stabilizer and may be added in order to suppress the generation of side reactions or byproducts that may be accompanied by unnecessary reactions of the etchant composition or the object to be etched.

The surfactant may be additionally added for the purpose of improving wettability of the etchant composition, improving foam properties of the additive, and increasing solubility of other organic additives. The surfactant may be 1 or 2 or more selected from nonionic surfactants, anionic surfactants, cationic surfactants, and amphoteric surfactants, and may be added in an amount of 0.0005 to 5% by weight based on the total weight of the composition, preferably 0.001 to 2% by weight based on the total weight of the composition. When the content of the surfactant is less than 0.0005% by weight based on the total weight of the composition, no effect can be expected, and when the content of the surfactant exceeds 5% by weight, solubility problems may occur, or process problems may occur due to excessive foaming.

The antioxidant and the corrosion inhibitor may be added in order to protect metals or metallic compounds used as materials for semiconductor devices. The antioxidant and the corrosion inhibitor may be used without limitation as long as they are commonly used in the art. For example, it may include, but not limited to, an azole-based compound, and may be added in an amount of 0.01 to 10% by weight based on the total weight of the composition.

According to another embodiment of the present invention, there is provided a semiconductor device or semiconductor apparatus manufactured using the composition for selective etching of silicon as described above. In addition, it is possible to provide a method of manufacturing a semiconductor device or semiconductor apparatus using the composition for selective etching of silicon of the present invention.

The etching method using the etching composition of the present invention may be performed according to a conventional method, and is not particularly limited.

Hereinafter, embodiments of the present invention will be described in detail so that those of ordinary skilled in the art can easily carry out the present invention. However, the present invention may be embodied in several different forms and is not limited to the embodiments described herein.

### EXAMPLES AND COMPARATIVE EXAMPLES

Compositions for selective etching of silicon were prepared with the composition shown in Table 1. Each composition comprises the amount of water such that the total weight of the composition is 100% by weight.

TABLE 1

| | Content (wt %) | | | | | |
|---|---|---|---|---|---|---|
| | Fluoric | Nitric | Phosphoric | Acetic | Auxiliary | |
| | acid | acid | acid | acid | oxidizing agent | |
| Comparative | 4.0 | 50.0 | — | 21.0 | — | |
| Example 1 | | | | | | |
| Comparative | 4.0 | 50.0 | 10.0 | 8.8 | — | |
| Example 2 | | | | | | |
| Example 1 | 4.0 | 50.0 | 10.0 | 8.8 | TBA | 0.1 |
| Example 2 | 4.0 | 50.0 | 10.0 | 8.8 | TBA | 3.0 |
| Example 3 | 4.0 | 50.0 | 10.0 | 8.8 | TBA | 5.0 |
| Example 4 | 4.0 | 50.0 | 10.0 | 8.8 | DCHA | 0.1 |
| Example 5 | 4.0 | 50.0 | 10.0 | 8.8 | DCHA | 3.0 |
| Example 6 | 4.0 | 50.0 | 10.0 | 8.8 | DCHA | 5.0 |
| Example 7 | 4.0 | 50.0 | 10.0 | 8.8 | TBN | 3.0 |
| Example 8 | 4.0 | 50.0 | 10.0 | 8.8 | IPN | 3.0 |
| Example 9 | 4.0 | 50.0 | 10.0 | 8.8 | BN | 3.0 |
| Example 10 | 4.0 | 50.0 | 10.0 | 8.8 | EN | 3.0 |

TBA: tetrabutylammonium nitrite
DCHA: dicyclohexylamine nitrite
TBN: tert-butyl nitrite
IPN: isopentyl nitrite
BN: butyl nitrite
EN: ethyl nitrite

### Experimental Example 1: Evaluation of Etch Rate

In order to determine the etch rate for each composition, the substrate to be evaluated having both silicon oxide film and silicon exposed on the surface was cut to 20×20 mm, and the thickness and weight of each substrate were measured. The etchant composition according to each of Examples and Comparative Examples was introduced into a thermostat maintained at 25° C. and the substrate to be evaluated was immersed for 4 minutes to carry out the etching process. After the etching was completed, the substrate was washed with ultrapure water and then the remaining etchant composition and moisture were completely dried using a drying device. Then, the weight of the dried substrate was measured, the weight change before and after evaluation was calculated, and the etch rate was measured using Equation 1 below.

(Initial substrate thickness×weight reduction rate)/Processing time=Etch rate [Equation 1]

The results are shown in Table 7.

TABLE 2

| | Etch rate | | |
|---|---|---|---|
| | (μm/min) | | Selectivity |
| | Si | SiO₂ | Si/SiO₂ |
| Comparative | 5.0 | 0.11 | 45 |
| Example 1 | | | |
| Comparative | 6.2 | 0.10 | 62 |
| Example 2 | | | |
| Example 1 | 9.4 | 0.12 | 78 |
| Example 2 | 10.0 | 0.13 | 77 |
| Example 3 | 11.8 | 0.12 | 98 |
| Example 4 | 9.3 | 0.14 | 66 |
| Example 5 | 10.2 | 0.15 | 68 |
| Example 6 | 10.9 | 0.15 | 73 |
| Example 7 | 9.2 | 0.14 | 66 |
| Example 8 | 9.0 | 0.13 | 69 |
| Example 9 | 8.7 | 0.13 | 67 |
| Example 10 | 8.5 | 0.13 | 65 |

As shown in Table 2, it is confirmed that the etch rate of silicon according to Examples of the present invention is 8 μm/min or more, and at the same time, the etching selectivity of silicon (Si) to the silicon oxide film (SiO₂) is 60 or more, indicating that the selective etching performance of silicon is excellent.

On the other hand, in Comparative Examples, it is confirmed that since the etch rate of silicon is about 6 μm/min or less and the selectivity is about 60 or less, indicating the selective etching effect of silicon is not sufficient.

As described above, the specific parts of the present invention have been described in detail, and for those of ordinary skilled in the art to which the present invention pertains, it is clear that these specific techniques merely describe a preferred embodiment and the scope of the present invention is not limited thereto. Those of ordinary skilled in the art to which the present invention pertains will be able to make various applications and modifications within the scope of the present invention based on the above contents. Accordingly, the substantial scope of the present invention will be defined by the appended claims and their equivalents.

What is claimed is:

1. A composition for selective etching of silicon, comprising:
a fluorine compound;
nitric acid;
phosphoric acid;
acetic acid; and
a nitrite compound.

2. The composition for selective etching of silicon according to claim 1, wherein the fluorine compound comprises one or more of hydrofluoric acid, ammonium bifluoride, sodium fluoride, potassium fluoride, aluminum fluoride, fluoroboric acid, ammonium fluoride, sodium bifluoride, potassium bifluoride, and ammonium tetrafluoroborate.

3. The composition for selective etching of silicon according to claim 1, wherein the nitrite compound has a structure of chemical formula 1 or chemical formula 2: 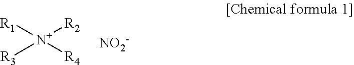
wherein R₁ to R₄ are each independently a hydrogen atom, C₁₋₆ alkyl or C₃₋₈ cycloalkyl; 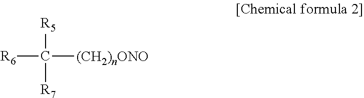
wherein
R₅ to R₇ are each independently a hydrogen atom or C₁₋₃ alkyl; and
n is an integer of 0 to 6.

4. The composition for selective etching of silicon according to claim 1, wherein the nitrite compound comprises one or more of tetrabutylammonium nitrite, dicyclohexylamine nitrite, tert-butyl nitrite, isopentyl nitrite, butyl nitrite, ethyl nitrite, isobutyl nitrite, and pentyl nitrite.

5. The composition for selective etching of silicon according to claim 1, wherein the etch rate of silicon is 7 μm/min or more, and the etch selectivity of silicon to the silicon oxide film is 50 or more.

6. A method for preparing a composition for selective etching of silicon, comprising mixing, based on the total weight of the composition,
0.01 to 20% by weight of a fluorine compound;
20 to 90% by weight of nitric acid;
0.1 to 20% by weight of phosphoric acid;
0.01 to 10% by weight of acetic acid; and
0.001 to 15% by weight of a nitrite compound.

7. The method for preparing a composition for selective etching of silicon according to claim 6, wherein the nitrite compound comprises one or more of tetrabutylammonium nitrite, dicyclohexylamine nitrite, tert-butyl nitrite, isopentyl nitrite, butyl nitrite, ethyl nitrite, isobutyl nitrite, and pentyl nitrite.

8. A semiconductor device manufactured using the composition for selective etching of silicon of claim 1.
